(19) United States
(12) Patent Application Publication
(10) Pub. No.: US 2001/0052319 A1
(43) Pub. Date: Dec. 20, 2001

(54) Plasma processing apparatus and plasma processing method

(75) Inventor: Shigenori Sakamori, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 09/737,484

(22) Filed: Dec. 18, 2000

(30) Foreign Application Priority Data
Jun. 7, 2000 (JP) 2000-170550(P)

(51) Int. Cl. C23C 16/00

(52) U.S. Cl. 118/722

(57) ABSTRACT

The plasma processing apparatus includes an electrostatic adhesion electrode for having a wafer electrostatically adhere to it, a helium gas introducing element for introducing a helium gas in a pressure-controlled manner between the wafer and the electrostatic adhesion electrode when the wafer adheres electrostatically, and a rear surface pressure setting element for setting the pressure of the helium gas to a first pressure during the preliminary adhering step and for setting the pressure of the helium gas to a second pressure higher than the first pressure in the steady state after plasma ignition.

### BACKGROUND OF THE INVENTION

1. Field of the Invention

The present invention relates to a plasma processing apparatus and a plasma processing method for a semiconductor wafer (hereinafter, simply referred to as a “wafer”) used in the production of a semiconductor element such as an IC (Integrated Circuit) and an LSI (Large Scale Integration) circuit.

2. Description of the Background Art

With further miniaturization and higher integration being achieved in the semiconductor devices, there has arisen a need to form the interconnections in many layers. For instance, six layers of interconnections are required. In general, the interconnections are formed by deposition of each layer by plasma processing.

Generally, when many layers need to be formed, the deposition is successively effected only on the front surface of the wafer so that there is a tendency for the wafer, wafer 10, to warp to a large degree, as shown in FIGS. 5A and 5B. Since the manner of warping varies depending on whether the surface on which to effect the deposition is a front surface or a rear surface and on the type of the deposited film, the warp may be salient in shape as shown in FIG. 5A or reentrant in shape as shown in FIG. 5B. It is known that the amount of warping in a wafer on which many layers are deposited to produce a semiconductor device is, in general, approximately 100 μm at maximum.

As shown in FIG. 6, in general, wafer 10 is electrostatically adhered to an electrostatic adhesion electrode 11 when performing the deposition to the wafer. In this case, in order to promote the heat exchange on the rear surface of wafer 10, a helium gas is introduced at more than a prescribed pressure to the rear surface of wafer 10, i.e. between wafer 10 and electrostatic adhesion electrode 11. When wafer 10 is warped as described above, however, the helium gas introduced to the rear surface of wafer 10 may leak from the periphery of wafer 10 so that wafer 10 does not adhere properly, or the pressure of the helium gas on the rear surface of wafer 10 (hereinafter referred to as a “rear surface pressure”) does not rise in a normal manner. These problems that may arise are the so-called “adhesion errors.”

Thus, an object of the present invention is to provide a plasma processing apparatus and a plasma processing method that circumvent such adhesion errors.

### SUMMARY OF THE INVENTION

To achieve the above object, according to one aspect of the plasma processing apparatus of the present invention, the plasma processing apparatus includes an electrostatic adhesion electrode for having a wafer electrostatically adhere to it, a helium gas introducing element for introducing a helium gas in a pressure-controlled manner between the wafer and the electrostatic adhesion electrode when the wafer adheres electrostatically, and a rear surface pressure setting element for setting the pressure of the helium gas to a first pressure during the preliminary adhering step and for setting the pressure of the helium gas to a second pressure higher than the first pressure in the steady state after plasma ignition.

By employing the above arrangement, the adhesion errors due to the leakage and the like can be avoided by setting the rear surface pressure to a low pressure while the strength of adhesion is weak before the plasma ignition, and the pressure can be raised to the necessary high level to achieve the heat exchange function after the strength of adhesion becomes stronger by the plasma ignition. In this manner, the adhesion errors can be effectively avoided without degrading the function.

In the above invention, the force exerted on the wafer by the first pressure preferably is smaller than the strength of adhesion between the wafer and the electrostatic adhesion electrode before the plasma ignition.

By employing the above arrangement, the wafer can be prevented from being detached in the stage of preliminary adhesion, since the force with which the rear surface pressure presses against the wafer exceeds the strength of adhesion by electrostatic adhesion.

According to another aspect of the plasma processing apparatus of the present invention, the plasma processing apparatus includes an electrostatic adhesion electrode for having a wafer electrostatically adhere to it, a helium gas introducing element for introducing a helium gas in a pressure-controlled manner between the wafer and the electrostatic adhesion electrode when the wafer adheres electrostatically, and a helium gas introduction start time control element for starting the introduction of the helium gas after the plasma ignition within 200 milliseconds from the plasma ignition.

By employing the above arrangement, the adhesion errors can be avoided even when the rear surface pressure is set to a high pressure since the helium gas is introduced after the plasma ignition. Moreover, since the introduction of the helium gas can be started sufficiently early, i.e., as early as 200 milliseconds from plasma ignition, the wafer temperature can be prevented from rising too high.

In the above invention, the surface of the electrostatic adhesion electrode to which the wafer is adhered electrostatically preferably is reentrant in shape. With this arrangement, the outer peripheries of the wafer and the electrostatic adhesion electrode make line-contact so that the leakage is even more effectively prevented, whereby the adhesion errors can be avoided.

In the above invention, the depth of the reentrant shape is approximately 50 μm. By employing this arrangement, in general, effective adhesion can be provided for the wafer with a warp of about 100 μm at maximum.

According to one aspect of the plasma processing method of the present invention, the plasma processing method includes a preliminary adhesion step of having a wafer electrostatically adhere to an electrostatic adhesion electrode by introducing a helium gas between the wafer and the electrostatic adhesion electrode in a pressure-controlled manner such that the helium gas attains a first pressure, and a post-plasma ignition step of pressure-controlling the helium gas such that it attains a second pressure higher than the first pressure at the same time as the plasma ignition.

By using the above method, the adhesion errors due to the leakage and the like can be avoided by setting the rear surface pressure to a low pressure while the strength of adhesion is weak before the plasma ignition. After the strength of adhesion becomes stronger by the plasma ignition, the pressure is raised to the necessary high level to achieve the heat exchange function. In this manner, the adhesion errors can be effectively avoided without degrading the function.

In the above invention, the first pressure preferably is smaller than the adhesion pressure between the wafer and the electrostatic adhesion electrode before the plasma ignition. By employing the above method, the adhesion pressure overcomes the rear surface pressure so that the wafer can be prevented from being detached in the stage of the preliminary adhesion.

According to another aspect of the plasma processing method of the present invention, the plasma processing method includes a plasma ignition step of causing plasma ignition, and a helium gas introduction step of starting the introduction of the helium gas between the wafer and the electrostatic adhesion electrode within 200 milliseconds from the plasma ignition.

By employing the above method, the adhesion errors can be avoided even when the rear surface pressure is set to a high pressure since the helium gas is introduced after the plasma ignition. Moreover, since the introduction of the helium gas can be started sufficiently early, i.e., as early as 200 milliseconds from the plasma ignition, the wafer temperature can be prevented from rising too high.

According to one aspect, the semiconductor device according to the present invention is produced using one of the above-described plasma processing apparatuses. In addition, according to another aspect, the semiconductor device according to the present invention is produced using one of the above-described plasma processing methods. Since the adhesion errors can be avoided with this arrangement, the stable high-quality semiconductor devices can be produced with high yield.

According to one aspect of the manufacturing method of the semiconductor device according to the present invention, the manufacturing method includes a step of utilizing one of the above-described plasma processing apparatuses. In addition, according to another aspect of the manufacturing method of the semiconductor device according to the present invention, the manufacturing method includes a step of utilizing one of the above-described plasma processing methods. With this arrangement, the adhesion errors can be avoided and the stable high-quality semiconductor devices can be produced with high yield.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a graph showing the changes in the rear surface pressure according to the first embodiment of the present invention.

FIG. 2 is a conceptual diagram representing the arrangement of the plasma processing apparatus according to the first embodiment of the present invention.

FIG. 3 is a graph showing the changes in the rear surface pressure according to the second embodiment of the present invention.

FIG. 4 is a conceptual diagram representing the arrangement of the plasma processing apparatus according to the third embodiment of the present invention.

FIGS. 5A and 5B are conceptual diagrams showing common examples of warping of wafers.

FIG. 6 is a conceptual diagram illustrating the problem found in a prior art plasma processing apparatus.

### DESCRIPTION OF THE PREFERRED EMBODIMENTS

First Embodiment

In general, in a plasma processing apparatus, a wafer adheres to an electrode in advance prior to the plasma ignition. During this preliminary adhesion stage, a preliminary adhesion determination is performed to determine whether the adhesion of the wafer is established or not. The preliminary adhesion determination involves introducing a helium gas to the rear surface of the wafer, detecting the rear surface pressure, and determining whether the rear surface pressure has attained the determination reference pressure.

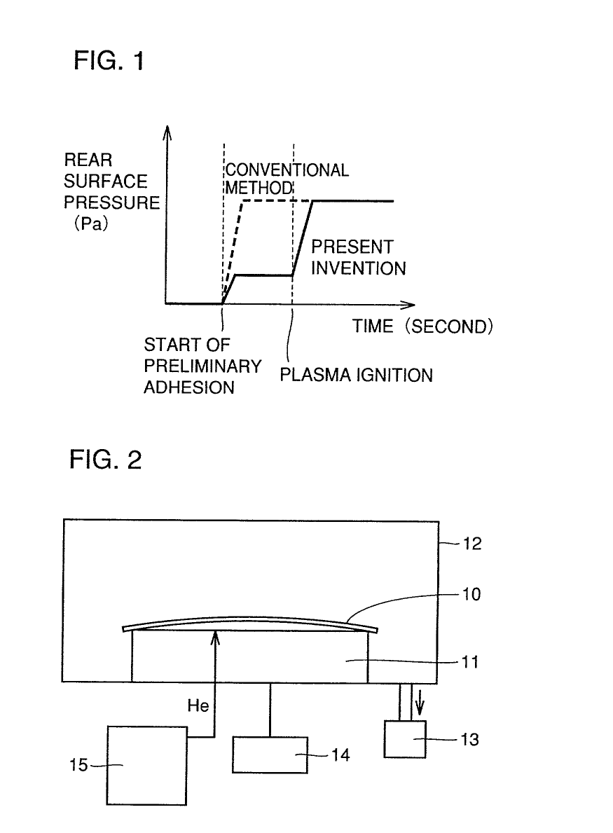

Conventionally, as shown by the broken line in FIG. 1, the rear surface pressure in the steady state after plasma ignition was at 30 torr (mmHg) or approximately 4000 Pa, as was the rear surface pressure in the preliminary adhesion stage. The determination reference pressure was also approximately 4000 Pa.

As shown in FIG. 2, the plasma processing apparatus according to the first embodiment is provided with a chamber 12, a vacuum pump 13 for evacuating chamber 12, an electrostatic adhesion electrode 11 disposed within chamber 12 for having a wafer 10 adhere to it, an RF (radio frequency) power supply and electrostatic adhesion power supply 14 for applying a voltage to electrostatic adhesion electrode 11, and a helium gas supply device 15 serving as a helium gas introduction element for introducing the helium gas in a pressure-controlled manner. Helium gas supply device 15 includes a manometer, a flow meter, and a pressure control valve.

In this plasma processing apparatus, as shown by the solid line in FIG. 1, the rear surface pressure in the steady state after plasma ignition is also approximately 4000 Pa as in the conventional case; however, a rear surface pressure setting element is provided for setting the pressure to a lower level, i.e., 10 torr (mmHg) or approximately 1333 Pa, during the preliminary adhesion stage. Thus, the determination reference pressure is accordingly set to approximately 1333 Pa.

With this plasma processing apparatus, the preliminary adhesion determination is performed at this low pressure, and the transition to a higher pressure is started at the same time as the plasma ignition as shown by the solid line in FIG. 1. Thus, the pressure in the steady state after plasma ignition reaches approximately 4000 Pa as in the conventional case.

In general, the higher the rear surface pressure, the more readily the leakage may occur. In addition, the strength of adhesion between wafer 10 and electrostatic adhesion electrode 11 increases after the plasma ignition as compared with before the plasma ignition.

In the plasma processing apparatus according to the first embodiment, the possibility of the leakage can be reduced in the preliminary adhesion stage since the rear surface pressure is kept low. Moreover, the strength of adhesion between wafer 10 and electrostatic adhesion electrode 11 is increased after the plasma ignition so that the possibility of the leakage is low even when the rear surface pressure is changed to a normally used high pressure. Therefore, the plasma processing itself can be performed stably under the conventional rear surface pressure conditions.

Preferably, the rear surface pressure at the time of the preliminary adhesion is smaller than the adhesion pressure between the wafer and the electrostatic adhesion electrode. Thus, the wafer can be kept from being detached in the stage of preliminary adhesion, and the leakage can be prevented.

Second Embodiment

The arrangement of the plasma processing apparatus according to the second embodiment is substantially the same as the one shown in FIG. 2. With this plasma processing apparatus, however, the preliminary adhesion is not performed prior to the plasma ignition. In this case, wafer 10 would move by the rear surface pressure if the helium gas is introduced before the plasma ignition in this condition without the preliminary adhesion. Thus, the helium gas is introduced after the plasma ignition.

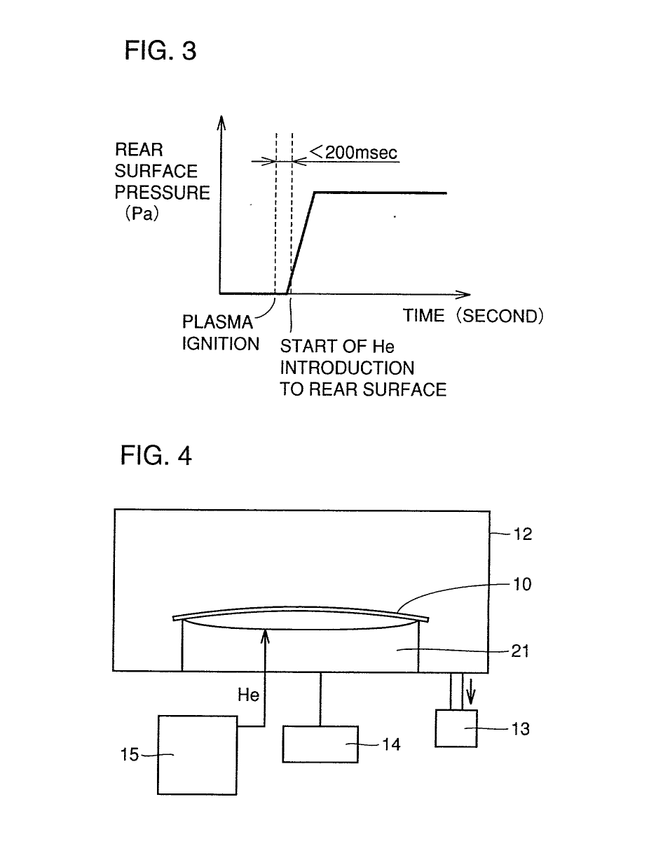

In place of the a rear surface pressure setting element of the first embodiment, this plasma processing apparatus is provided with a helium gas introduction start time control element for starting the introduction of the helium gas within 200 milliseconds from the plasma ignition as shown in FIG. 3.

Thus, the introduction of the helium gas is started after the plasma ignition and within 200 milliseconds from the plasma ignition, and thereafter the rear surface pressure rises to the steady state, as shown in FIG. 3.

Since the helium gas is introduced after the plasma ignition takes place, the strength of adhesion between wafer 10 and electrostatic adhesion electrode 11 is already at a high level due to the plasma ignition. Thus, the leakage can be prevented even when the rear surface pressure is set to a high pressure from the beginning.

Moreover, if the helium gas is not introduced after the plasma ignition or the helium gas is introduced with a delay after the plasma ignition, sufficient heat exchange does not take place so that the temperature of wafer 10 may rise to an extreme level. Here, however, since the introduction of the helium gas is started sufficiently early, i.e., as early as 200 milliseconds from the plasma ignition, the plasma processing can be performed without the wafer temperature rising too high.

Third Embodiment

The arrangement of the plasma processing apparatus according to the third embodiment is shown in FIG. 4. This arrangement is basically the same as the one described in relation to the first embodiment (see FIG. 2), but an electrostatic adhesion electrode 21 whose wafer-adhering surface is reentrant in shape is disposed in place of electrostatic adhesion electrode 11.

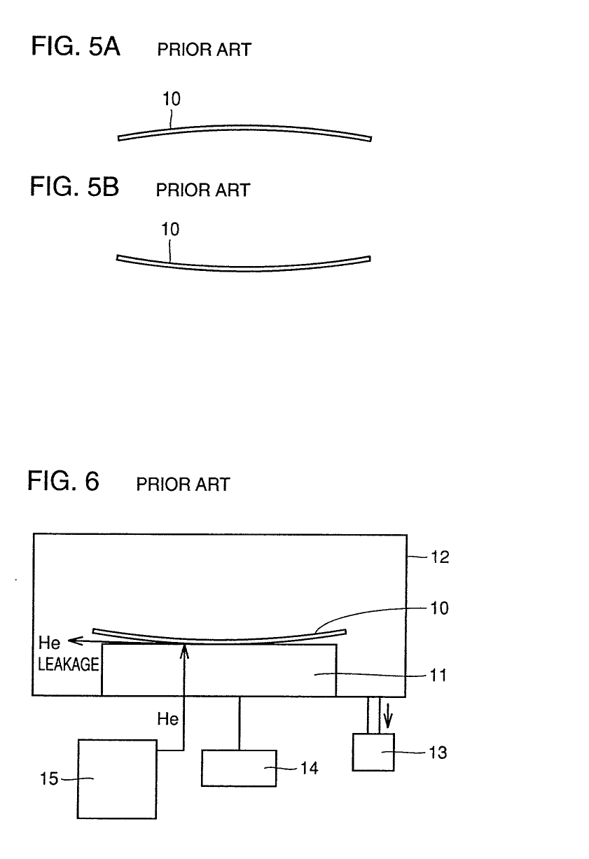

Generally, in most cases in the state-of-the-art interconnection process steps, wafer 10 deforms into a salient shape, as shown in FIG. 5A. Thus, as shown in FIG. 4, the salient wafer 10 is placed on electrostatic adhesion electrode 21 having a reentrant adhesion surface, thereby a line-contact is formed between wafer 10 and electrostatic adhesion electrode 21 at their outer peripheries. Although the area of contact is limited in the line-contact, a more reliable contact between wafer 10 and electrostatic adhesion electrode 21 can be ensured. As a consequence, an even more reliable adhesion is established, and the leakage is even more effectively prevented.

As mentioned earlier, in general, since it is known that the amount of warping in a wafer on which many layers are deposited is approximately 100 μm at maximum, the depth of the reentrant shape of electrostatic adhesion electrode 21 preferably is about half the size, which is approximately 50 μm. If the reentrant shape is too shallow, the effect of it being a reentrant shape is decreased. On the other hand, if the reentrant shape is too deep, it merely requires more work effort to process the adhesion surface and no merit is provided.

Although the description is provided here in relation to the example in which electrostatic adhesion electrode 21 whose adhesion surface is reentrant is applied to the plasma processing apparatus of the first embodiment, electrostatic adhesion electrode 21 can also be applied to the plasma processing apparatus of the second embodiment with the same effects achieved.

According to the present invention, the magnitude of the rear surface pressure is changed according to the change in the adhesion strength before and after the plasma ignition in order to avoid the adhesion errors due to leakage and the like. Thus, adhesion errors can be prevented effectively.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A plasma processing apparatus, comprising:
an electrostatic adhesion electrode for having a wafer electrostatically adhere to it;
helium gas introducing means for introducing a helium gas in a pressure-controlled manner between said wafer and said electrostatic adhesion electrode when said wafer adheres electrostatically; and
rear surface pressure setting means for setting a pressure of said helium gas to a first pressure during a preliminary adhering step and for setting the pressure of said helium gas to a second pressure higher than said first pressure in a steady state after plasma ignition.

2. The plasma processing apparatus according to claim 1, wherein a force exerted on said wafer by said first pressure is smaller than adhesion strength between said wafer and said electrostatic adhesion electrode before the plasma ignition.

3. The plasma processing apparatus according to claim 1, wherein a surface of said electrostatic adhesion electrode to which said wafer is adhered electrostatically is reentrant in shape.

4. The plasma processing apparatus according to claim 3, wherein a depth of said reentrant shape is approximately 50 μm.

5. A plasma processing apparatus, comprising:
an electrostatic adhesion electrode for having a wafer electrostatically adhere to it;
helium gas introducing means for introducing a helium gas in a pressure-controlled manner between said wafer and said electrostatic adhesion electrode when said wafer adheres electrostatically; and
helium gas introduction start time control means for starting introduction of said helium gas after plasma ignition within 200 milliseconds from the plasma ignition.

6. The plasma processing apparatus according to claim 5, wherein an electrostatic adhesion by said electrostatic adhesion electrode is not performed prior to the plasma ignition but after said plasma ignition.

7. A plasma processing method, comprising:
a preliminary adhesion step of having a wafer electrostatically adhere to an electrostatic adhesion electrode by introducing a helium gas between said wafer and said electrostatic adhesion electrode in a pressure-controlled manner such that the helium gas attains a first pressure; and
a post-plasma ignition step of pressure-controlling said helium gas such that said helium gas attains a second pressure higher than said first pressure at a same time as plasma ignition.

8. The plasma processing method according to claim 7, wherein said first pressure is smaller than adhesion pressure between said wafer and said electrostatic adhesion electrode before the plasma ignition.

9. The plasma processing method according to claim 7, wherein a surface of said electrostatic adhesion electrode to which said wafer is adhered electrostatiscally is reentrant in shape.
